(19) United States
(12) Patent Application Publication
(10) Pub. No.: US 2014/0224517 A1
(43) Pub. Date: Aug. 14, 2014

(54) LAMINATED FILM AND ELECTRONIC DEVICE

(71) Applicant: Akira Hasegawa, Tsukuba-shi (JP)

(72) Inventor: Akira Hasegawa, Tsukuba-shi (JP)

(73) Assignee: SUMITOMO CHEMICAL COMPANY, LIMITED, Tokyo (JP)

(21) Appl. No.: 14/127,375

(22) PCT Filed: Jun. 21, 2012
(86) PCT No.: PCT/JP2012/065896

§ 371 Date: Mar. 18, 2014

(30) Foreign Application Priority Data
Jun. 21, 2011 (JP) 2011-137397

(51) Int. Cl. C09D 5/00; H05K 7/06

(52) U.S. Cl. CPC C09D 5/00; H05K 7/06
USPC 174/50.5; 428/336; 524/860; 428/447

(57) ABSTRACT

Provided is a laminated film comprising a substrate, and at least one layer of film layer that is formed on at least one surface of the substrate, wherein at least one layer of the film layer contains silicon, oxygen, and hydrogen, a ratio of a total value of Q¹, Q², and Q³ peak areas to a Q⁴ peak area on the basis of an abundance ratio of silicon atoms having different bonding states to oxygen atoms, which are obtained by ²⁹Si solid-state NMR measurement of the film layer, satisfies the following conditional expression (I):

(total value of Q¹, Q², and Q³ peak areas)/(Q⁴ peak area)<1.0 (I)
wherein Q¹ represents a silicon atom that is bonded to one neutral oxygen atom and three hydroxyl groups, Q² represents a silicon atom that is bonded to two neutral oxygen atoms and two hydroxyl groups, Q³ represents a silicon atom that is bonded to three neutral oxygen atoms and one hydroxyl group, and Q⁴ represents a silicon atom that is bonded to four neutral oxygen atoms.

### TECHNICAL FIELD

The present invention relates to a laminated film having gas barrier properties, and an electronic device including the laminated film. Priority is claimed on Japanese Patent Application No. 2011-137397, filed Jun. 21, 2011, the content of which is incorporated herein by reference.

### BACKGROUND ART

A gas barrier film can be appropriately used as a packaging container suitable for filling and packaging of articles such as foods, cosmetics, and detergents. Recently, a gas barrier film, which uses a plastic film and the like as a substrate and which is constituted by forming a film on one surface of the substrate using a material such as silicon oxide, silicon nitride, silicon oxynitride, and aluminum oxide as a forming material, has been suggested.

As a method of forming the film on a surface of the plastic substrate, a physical vapor deposition (PVD) method such as a vacuum deposition method, a sputtering method, and an ion plating method, and a chemical vapor deposition (CVD) method such as a pressure-reduced chemical vapor deposition method and a plasma chemical vapor deposition method are known. In addition, as a laminated film that is formed by these film formation methods, for example, PTL 1 discloses a laminated film that is obtained by providing a silicon-oxide-based film on a surface of a plastic substrate.

### CITATION LIST

### Patent Literature

[PTL 1] Japanese Unexamined Patent Application, First Publication No. 2010-260347

### SUMMARY OF INVENTION

### Technical Problem

However, the laminated film that is disclosed in PTL 1 described above is excellent in bendability, but a further improvement in gas barrier properties is required.

The invention has been made in consideration of the above-described circumstances, and an object thereof is to provide a laminated film having high gas barrier properties.

### Solution to Problem

The gas barrier properties can be evaluated as water vapor permeability (also referred to as a water vapor transmittance). The water vapor permeability becomes an index indicating that the lower the water vapor permeability, the better the gas barrier property.

The invention includes the following aspects.

According to a first aspect of the invention, a laminated film is provided, comprising a substrate; and at least one layer of film layer that is formed on at least one surface of the substrate,

wherein at least one layer of the film layer contains silicon, oxygen, and hydrogen,

a ratio of a total value of Q¹, Q², and Q³ peak areas to a Q⁴ peak area on the basis of an abundance ratio of silicon atoms having different bonding states to oxygen atoms, which are obtained by ²⁹Si solid-state NMR measurement of the film layer, satisfies the following conditional expression (I):

(total value of Q¹, Q², and Q³ peak areas)/(Q⁴ peak area)<1.0 (I),

wherein Q¹ represents a silicon atom that is bonded to one neutral oxygen atom and three hydroxyl groups, Q² represents a silicon atom that is bonded to two neutral oxygen atoms and two hydroxyl groups, Q³ represents a silicon atom that is bonded to three neutral oxygen atoms and one hydroxyl group, and Q⁴ represents a silicon atom that is bonded to four neutral oxygen atoms.

According to a second aspect of the invention, in the laminated film according to the first aspect, the film layer further contains carbon atoms.

According to a third aspect of the invention, in the laminated film according to the first or second aspect, the film layer is a layer that is formed by a plasma chemical vapor deposition method.

According to a fourth aspect of the invention, in the laminated film according to the third aspect, a film-forming gas that is used in the plasma chemical vapor deposition method contains an organic silicon compound and oxygen.

According to a fifth aspect of the invention, in the laminated film according to the fourth aspect, the film layer is a layer that is formed under conditions in which a content of oxygen in the film-forming gas is set to be equal to or less than a theoretical amount of oxygen necessary to completely oxidize a total amount of the organic silicon compound in the film-forming gas.

According to a sixth aspect of the invention, in the laminated film according to any one of third to fifth aspects, the film layer is a layer formed using discharge plasma of a film-forming gas that is a forming material of the film layer, which is generated in a space between a first film-forming roll and a second film-forming roll by applying an alternating-current voltage between the first film-forming roll around which the substrate is wound and the second film-forming roll that is opposite to the first film-forming roll and around which the substrate is wound downstream of a conveying route of the substrate in relation to the first film-forming roll.

According to a seventh aspect of the invention, in the laminated film according to the sixth aspect, the film layer is a layer that is formed by conveying the substrate to overlap first discharge plasma formed along tunnel-shaped magnetic fields by forming endless tunnel-shaped magnetic fields in a space between the first film-forming roll and the second film-forming roll that are opposite to each other, and second discharge plasma that is formed at the periphery of the tunnel-shaped magnetic field.

According to an eighth aspect of the invention, in the laminated film according to any one of the first to seventh aspects, the substrate has a strip shape, and the film layer is a layer that is continuously formed on the surface of the substrate while conveying the substrate in a longitudinal direction.

According to a ninth aspect of the invention, in the laminated film according to any one of first to eighth aspects, at least one kind of resin selected from the group consisting of a polyester-based resin and a polyolefin-based resin is used as the substrate.

According to a tenth aspect of the invention, in the laminated film according to the ninth aspect, the polyester-based resin is polyethylene terephthalate or polyethylene naphthalate.

According to an eleventh aspect of the invention, in the laminated film according to any one of the first to tenth aspects, the thickness of the film layer is 5 nm to 3000 nm.

According to a twelfth aspect of the invention, in the laminated film according to any one of the first to eleventh aspects, in a silicon distribution curve, an oxygen distribution curve, and a carbon distribution curve which indicate a relationship between a distance from a surface of the film layer in a thickness direction of the film layer, and a ratio of an amount of silicon atoms (atomic ratio of silicon) to a total amount of silicon atoms, oxygen atoms, and carbon atoms, a ratio of an amount of oxygen atoms (atomic ratio of oxygen) to the total amount, and a ratio of an amount of carbon atoms (atomic ratio of carbon) to the total amount, respectively, all of the following conditions (i) to (iii) are satisfied,

(i) the atomic ratio of silicon, the atomic ratio of oxygen, and the atomic ratio of carbon satisfy a condition expressed by the following expression (1) in a region of 90% or more of the thickness of the layer:

(atomic ratio of oxygen)>(atomic ratio of silicon)>(atomic ratio of carbon) (1), or

the atomic ratio of silicon, the atomic ratio of oxygen, and the atomic ratio of carbon satisfy a condition expressed by the following expression (2) in a region of 90% or more of the thickness of the layer:

(atomic ratio of carbon)>(atomic ratio of silicon)>(atomic ratio of oxygen) (2),

(ii) the carbon distribution curve has at least one extremal value, and

(iii) an absolute value of a difference between a maximum value and a minimum value of the atomic ratio of carbon in the carbon distribution curve is 5% by atom (that is, at %) or more.

According to a thirteenth aspect of the invention, in the laminated film according to the twelfth aspect, the carbon distribution curve may be substantially continuous.

According to a fourteenth aspect of the invention, in the laminated film according to the twelfth or thirteenth aspect, the oxygen distribution curve has at least one extremal value.

According to a fifteenth aspect of the invention, in the laminated film according to any one of the twelfth to fourteenth aspects, an absolute value of a difference between a maximum value and a minimum value of the atomic ratio of oxygen in the oxygen distribution curve is 5% by atom or more.

According to a sixteenth aspect of the invention, in the laminated film according to any one of the twelfth to fifteenth aspects, an absolute value of a difference between a maximum value and a minimum value of the atomic ratio of silicon in the silicon distribution curve is less than 5% by atom.

According to a seventeenth aspect of the invention, an electronic device is provided, comprising:

a functional element that is provided on a first substrate; and

a second substrate that is opposite to a surface of the first substrate on which the functional element is formed,

wherein the first substrate and the second substrate form at least a part of a sealing structure that seals the functional element in the inside of the sealing structure, and

at least one of the first substrate and the second substrate is the laminated film according to any one of the first to sixteenth aspects.

According to an eighteenth aspect of the invention, in the electronic device according to the seventeenth aspect, the functional element constitutes an organic electroluminescence element.

According to a nineteenth aspect of the invention, in the electronic device according to the seventeenth aspect, the functional element constitutes a liquid crystal display element.

According to a twentieth aspect of the invention, in the electronic device according to the seventeenth aspect, the functional element constitutes a photoelectric conversion element that receives light and generates electricity.

### Advantageous Effects of Invention

According to the invention, it is possible to provide a laminated film having high gas barrier properties.

### BRIEF DESCRIPTION OF DRAWINGS

FIG. 1 is a schematic diagram illustrating an example of a laminated film according to an embodiment.

FIG. 2 is a schematic diagram illustrating an embodiment of a manufacturing apparatus that is used to manufacture the laminated film.

FIG. 3 is a chart illustrating results of ²⁹Si solid-state NMR measurement.

FIG. 4 is a chart illustrating results of ²⁹Si solid-state NMR measurement.

FIG. 5 is a chart illustrating results of ²⁹Si solid-state NMR measurement.

FIG. 6 is a side cross-sectional diagram of an organic EL device that is an electronic device of the invention.

FIG. 7 is a side cross-sectional diagram of a liquid crystal display that is an electronic device of the invention.

FIG. 8 is a side cross-sectional diagram of a photoelectric conversion device that is an electronic device of the invention.

### DESCRIPTION OF EMBODIMENTS

### First Embodiment

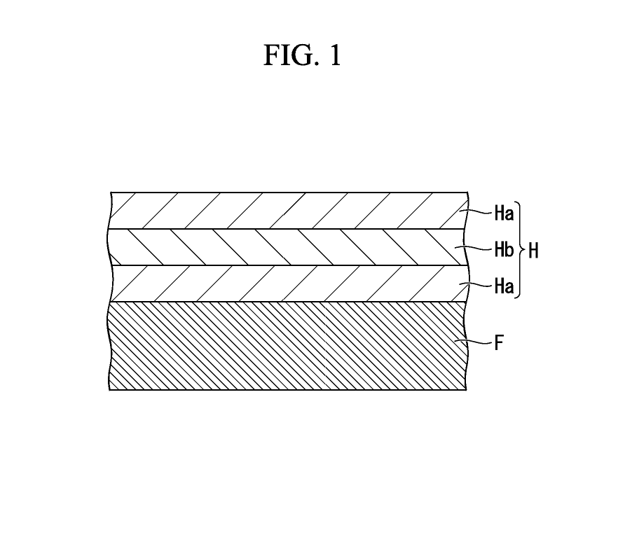

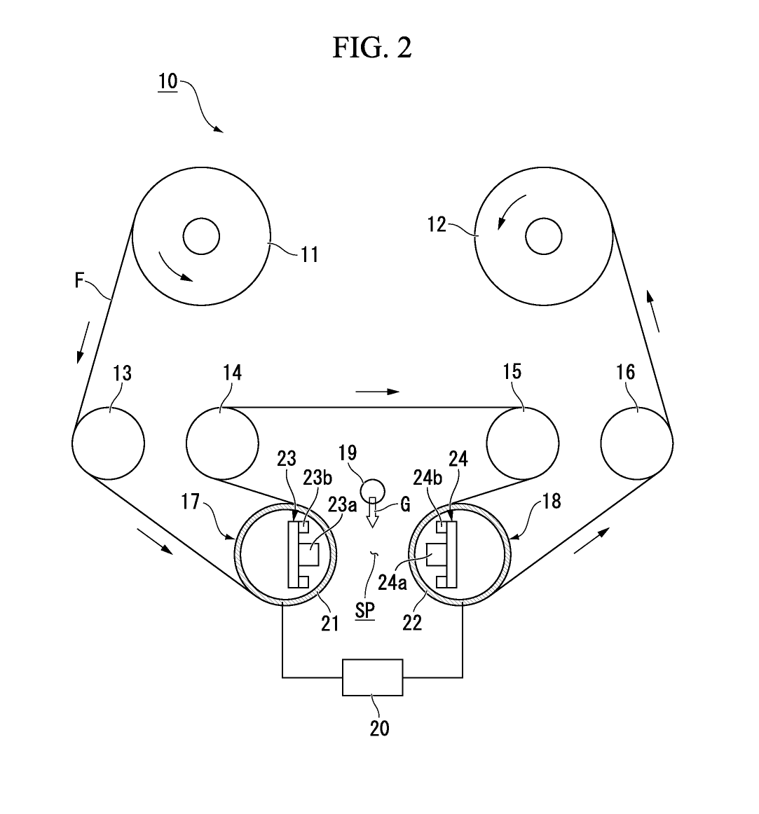

Hereinafter, a laminated film according to an embodiment of the invention will be described with reference to FIG. 1 and FIG. 2. In addition, in all of the following drawings, dimensions, ratios, and the like of respective components are appropriately made different for easy understanding of the drawings.

(Laminated Film)

FIG. 1 shows a schematic diagram illustrating an example of a laminated film of the embodiment. The laminated film of the embodiment is configured by laminating a film layer H that secures gas barrier properties on a surface of a substrate F. At least one layer of the film layer H contains silicon, oxygen, and hydrogen. The film layer H has a three-layer structure which includes a first layer Ha containing a large amount of SiO₂ formed by a complete oxidation reaction of a film-forming gas to be described later, and a second layer Hb containing a large amount of SiOₓC_{y} generated by an incomplete oxidation reaction, and in which the first layer Ha and the second layer Hb are alternately laminated.

However, the drawing schematically shows that a distribution is present in a film composition. However, actually, an interface is not clearly generated between the first layer Ha and the second layer Hb, and the composition continuously varies. A plurality of the film layers H may be laminated. A method of manufacturing the laminated film shown in FIG. 1 will be described later in detail.

(Film Layer)

In the film layer H provided to the laminated film of the embodiment, at least one layer thereof includes silicon, oxygen, and hydrogen. In addition, a ratio of a total value of Q¹, Q², and Q³ peak areas to a Q⁴ peak area which are obtained by ²⁹Si solid-state NMR measurement of the film layer H satisfies the following conditional expression (I).

(total value of Q¹, Q², and Q³ peak areas)/(Q⁴ peak area)<1.0 (I)

Here, Q¹, Q², Q³, and Q⁴ distinguishably represent silicon atoms that constitute the film layer H according to properties of oxygen bonded to each of the silicon atoms. That is, when an oxygen atom that forms a Si—O—Si bond is set to a “neutral” oxygen atom with respect to a hydroxyl group, respective symbols of Q¹, Q², Q³, and Q⁴ represent that the oxygen atom bonded to the silicon atom is as follows.

Q¹ represents a silicon atom that is bonded to one neutral oxygen atom and three hydroxyl groups.

Q² represents a silicon atom that is bonded to two neutral oxygen atoms and two hydroxyl groups.

Q³ represents a silicon atom that is bonded to three neutral oxygen atoms and one hydroxyl group.

Q⁴ represents a silicon atom that is bonded to four neutral oxygen atoms.

Here, in a case of measuring “²⁹Si solid-state NMR of the film layer H”, the substrate F may be included in a test specimen that is used in the measurement.

An area ratio of each peak which is obtained by the ²⁹Si solid-state NMR measurement represents an abundance ratio of the silicon atoms in each bonding state.

For example, the peak area of the solid-state NMR may be calculated as follows.

First, a spectrum obtained by the ²⁹Si solid-state NMR measurement is smoothed.

In the following description, a spectrum after the smoothing is referred to as a “measurement spectrum”. In the spectrum obtained by the ²⁹Si solid-state NMR measurement, noise having a frequency higher than that of a signal of the peak is frequently included, and thus this noise is removed by the smoothing. First, the spectrum obtained by the ²⁹Si solid-state NMR measurement is Fourier-transformed to remove a high frequency of 100 Hz or more. When the high-frequency noise of 100 Hz or more is removed, the spectrum is inversely Fourier-transformed, and this spectrum is referred to as a “measurement spectrum”.

Next, the measurement spectrum is divided into the respective Q¹, Q², Q³, and Q⁴ peaks. That is, parameters such as the height and half-value width of each of the peaks are optimized in order for a model spectrum obtained by adding up Q¹, Q², Q³, and Q⁴ to coincide with the measurement spectrum after the smoothing on the assumption that the Q¹, Q², Q³, and Q⁴ peaks exhibit Gauss distribution (normal distribution) curves centering around an intrinsic chemical shift, respectively.

The parameter optimization is carried out, for example, by using an iteration method. That is, a parameter, in which the sum of squares of differences between the model spectrum and the measurement spectrum converges to a minimum value, is calculated.

Next, the Q¹, Q², Q³, and Q⁴ peaks which are obtained in this manner are integrated, respectively, to calculate each peak area. The left-hand side (total value of Q¹, Q², and Q³ peak areas)/(Q⁴ peak area) of the expression (I) is obtained using the peak areas that are obtained in this manner and is used as an evaluation index of gas barrier properties.

That is, as a requirement of the laminated film of the embodiment, half or more of silicon atoms, which constitute the film layer H and which are quantified by the ²⁹Si solid-state NMR measurement, are necessary to be composed of the Q⁴ silicon atom. In the Q⁴ silicon atom, it is considered that the periphery of the silicon atom is surrounded by four neutral oxygen atoms, and the four neutral oxygen atoms are bonded to the silicon atom and form a net structure. On the contrary, the Q¹, Q², and Q³ silicon atoms are bonded to one or more hydroxyl groups, and thus it is considered that a minute gap, in which a covalent bond is not formed, is present between adjacent silicon atoms.

Accordingly, the more Q⁴ silicon atoms that are present, the denser the film layer H becomes, and thus a laminated film that realizes high gas barrier properties can be obtained. In this specification, according to examination by the present inventors, it is found that as expressed by the expression (I), when (total value of Q¹, Q², and Q³ peak areas)/(Q⁴ peak area) is less than 1, a laminated film exhibiting high gas barrier properties is obtained.

The value of (total value of Q¹, Q², and Q³ peak areas)/(Q⁴ peak area) is preferably 0.8 or less, and more preferably 0.6 or less.

That is, the value of (total value of Q¹, Q², and Q³ peak areas)/(Q⁴ peak area) is preferably 0 to 0.8, and more preferably 0 to 0.6 or less.

In the laminated film of the invention, the spectrum that is obtained by the ²⁹Si solid-state NMR measurement is measured by a CP method (Cross Polarization method). However, in a case where the spectrum is measured by a DD method (Dipolar Decoupling method), even when the value of (total value of Q¹, Q², and Q³ peak areas)/(Q⁴ peak area) is more than 1, a laminated film in this case is included in the laminated film of the invention, as long as (total value of Q¹, Q², and Q³ peak areas)/(Q⁴ peak area) is 1 or less when being measured by the CP method, the laminated film is a laminated film provided with a substrate and at least one layer of film layer formed on at least one surface of the substrate, and at least one layer of the film layer includes silicon, oxygen, and hydrogen.

The film layer H that is a target of the embodiment is a layer that is formed on at least one surface of the substrate F in the laminated film. In addition, at least one layer of the film layer H may further contain nitrogen, aluminum, and titanium. A configuration of the film layer H will be described later in detail.

In the laminated film of the embodiment, the thickness of the film layer H is preferably in a range of 5 nm to 3000 nm, more preferably in a range of 10 nm to 2000 nm, and still more preferably 100 nm to 1000 nm. When the thickness of the film layer is equal to or more than the lower limit, gas barrier properties such as an oxygen barrier property and a water-vapor barrier property are further improved. In addition, when the thickness is equal to or less than the upper limit, in a case where the film is bent, a further greater effect of suppressing a decrease in gas barrier properties can be obtained.

In addition, in a case where the laminated film of the embodiment has a barrier layer in which the film layer is laminated in two or more layers, the total thickness of these film layers (the thickness of the barrier film in which the film layers are laminated) is preferably more than 100 nm and equal to or less than 3000 nm. When the total thickness of the film layer is equal to or more than the lower limit, the gas barrier properties such as the oxygen gas barrier property and the water-vapor barrier property are further improved. In addition, when the total thickness is equal to or less than the upper limit, in a case where the film is bent, a further greater effect of suppressing a decrease in the gas barrier properties can be obtained. In addition, the thickness of each single film layer is preferably more than 50 nm.

(Substrate)

Examples of the substrate F that is used in the laminated film of the embodiment include a polyester resin such as polyethylene terephthalate (PET) and polyethylene naphthalate (PEN); a polyolefin resin such as polyethylene (PE), polypropylene (PP), and cyclic polyolefin; a polyamide resin; a polycarbonate resin; a polystyrene resin; a polyvinyl alcohol resin; a saponified product of ethylene-vinyl acetate copolymer; a polyacrylonitrile resin; an acetal resin; a polyimide resin; and polyether sulfide (PES). These resins can be used in combination of two or more kinds as necessary. The polyester resin and the polyolefin resin are preferably selected in accordance with necessary characteristics such as transparency, heat resistance, and linear expansion characteristics, and PET, PEN, and cyclic polyolefin are more preferable. Examples of a composite material containing a resin include a silicone resin such as polydimethyl siloxane and polysilsesquioxane, a glass composite substrate, a glass epoxy substrate, and the like. Among these resins, from the viewpoint of high heat resistance and a small linear expansion coefficient, a polyester-based resin, a polyolefin-based resin, the glass composite substrate, and the glass epoxy substrate are preferable. These resins can be used alone or in combination of two or more kinds.

When using a material including a silicone resin or glass as the substrate F, to avoid an effect from silicon in the substrate F during the solid-state NMR measurement, the film layer H is separated from the substrate F, and then the solid-state NMR measurement is carried out with respect to only the silicon contained in the film layer H.

Examples of separating the film layer H and the substrate F include a method in which the film layer H is scraped off by a metal spatula, and is collected in a sample tube used in the solid-state NMR measurement. The substrate F may be removed using a solvent that dissolves the substrate F alone, and then the film layer H that remains as a residue may be collected.

The thickness of the substrate F is appropriately set in consideration of stability during manufacturing of the laminated film, and the like. However, the thickness is preferably 5 μm to 500 μm in consideration of easy conveyance of the substrate F in a vacuum. Further, when forming the film layer H that is employed in the embodiment, as described later, discharge is carried out through the substrate F, and thus the thickness of the substrate is more preferably 50 μm to 200 μm, and particularly preferably 50 μm to 100 μm.

In addition, from the viewpoint of adhesiveness with the film layer H that is to be formed, the substrate F may be subjected to a surface activation treatment to clean a surface of the substrate F. Examples of the surface activation treatment include a corona treatment, a plasma treatment, and a flame treatment.

(Other Configurations)

The laminated film of the embodiment includes the substrate and the film layer, but may further include a primer coat layer, a heat-sealing resin layer, an adhesive layer, and the like as necessary. The primer coat layer can be formed using a known primer coat material capable of improving adhesiveness between the substrate and the film layer. The heat-sealing resin layer can be formed using an appropriate heat-sealing resin that is known. Further, the adhesive layer can be formed using an appropriate adhesive that is known, and a plurality of laminated films may be bonded to each other by the adhesive layer.

(Method of Manufacturing Laminated Film)

FIG. 2 shows a schematic diagram illustrating an embodiment of a manufacturing apparatus that is used to manufacture the laminated film. In addition, in FIG. 2, dimensions, ratios, and the like of respective components are appropriately made different for easy understanding of the drawings.

The manufacturing apparatus 10 shown in the drawing includes a delivery roll 11, a winding roll 12, conveying rolls 13 to 16, a film-forming roll (first film-forming roll) 17, a film-forming roll (second film-forming roll) 18, a gas supply tube 19, a power supply 20 for plasma generation, electrodes 21 and 22, a magnetic field-forming device 23 that is provided inside the film-forming roll 17, and a magnetic field-forming device 24 that is provided inside the film-forming roll 18. Among the components of the manufacturing apparatus 10, when manufacturing the laminated film, at least the film-forming rolls 17 and 18, the gas supply tube 19, and the magnetic field-forming devices 23 and 24 are disposed inside a vacuum chamber (not shown). The vacuum chamber is connected to a vacuum pump (not shown). A pressure inside the vacuum chamber is adjusted by operation of the vacuum pump.

When using the apparatus, discharge plasma of a film-forming gas supplied from the gas supply tube 19 can be generated in a space between the film-forming roll 17 and the film-forming roll 18 by controlling the power supply 20 for plasma generation, and thus plasma CVD film formation by a plasma chemical vapor deposition method can be carried out by using the discharge plasma that is generated.

A strip-shaped substrate F before film formation is provided to the delivery roll 11 in a state of being wound, and the delivery roll 11 delivers the substrate F while rolling it out in a longitudinal direction. The winding roll 12 is provided at an end side of the substrate F, and winds the substrate F after the film formation while pulling the substrate F to accommodate the substrate F in a roll shape.

The film-forming roll 17 and the film-forming roll 18 extend in parallel to each other and are disposed to be opposite to each other. Both of the rolls are formed from an electrically conductive material. The substrate F is wound around the film-forming roll 17. In addition, the substrate F is wound around the film-forming roll 18 that is disposed downstream of the conveying route of the substrate F in relation to the film-forming roll 17. The film-forming rolls 17 and 18 convey the substrate F while rotating, respectively. In addition, the film-forming roll 17 and the film-forming roll 18 are insulated from each other, and are connected to the common power supply 20 for plasma generation. When an alternating-current voltage is applied from the power supply 20 for plasma generation, electric fields are formed in a space SP between the film-forming roll 17 and the film-forming roll 18.

Further, the magnetic field-forming devices 23 and 24 are stored inside the film-forming roll 17 and the film-forming roll 18, respectively. The magnetic field-forming devices 23 and 24 are members that form magnetic fields in the space SP, and are stored not to rotate together with the film-forming roll 17 and the film-forming roll 18.

The magnetic field-forming devices 23 and 24 include central magnets 23a and 24a that extend in the same direction as an extending direction of the film-forming roll 17 and the film-forming roll 18, and annular ring-shaped external magnets 23b and 24b that are disposed to extend in the same direction as the extending direction of the film-forming roll 17 and the film-forming roll 18 while surrounding the periphery of the central magnets 23a and 24a, respectively. In the magnetic field-forming device 23, magnetic lines of force (magnetic fields) that connect the central magnet 23a and the external magnet 23b form an endless tunnel. Similarly, in the magnetic field-forming device 24, magnetic lines of force that connect the central magnet 24a and the external magnet 24b form an endless tunnel.

Discharge plasma of a film-forming gas is generated by magnetron discharge that occurs when the magnetic lines of force and alternating-current electric fields formed between the film-forming roll 17 and the film-forming roll 18 cross each other. That is, to be described later in detail, the space SP is used as a film-forming space in which the plasma CVD film forming is carried out, and a film layer formed using a film-forming gas as a film-forming material is formed on a surface (film-forming surface) of the substrate F which does not come into contact with the film-forming rolls 17 and 18.

The gas supply tube 19 which supplies a film-forming gas such as a raw material gas of the plasma CVD to the space SP is formed in the vicinity of the space SP. The gas supply tube 19 has a tubular shape that extends in the same direction as the extending direction of the film-forming roll 17 and the film-forming roll 18, and supplies the film-forming gas to the space SP from openings that are formed at a plurality of sites. In the drawing, a situation of supplying the film-forming gas toward the space SP from the gas supply tube 19 is indicated by an arrow.

The raw material gas can be appropriately selected and used in accordance with a material quality of a barrier film to be formed. As the raw material gas, for example, an organic silicon compound that contains silicon can be used. Examples of the organic silicon compound include hexamethyldisiloxane, 1,1,3,3-tetramethyldisiloxane, vinyltrimethylsilane, methyltrimethylsilane, hexamethyldisilane, methylsilane, dimethylsilane, trimethylsilane, diethylsilane, propylsilane, phenylsilane, vinyltriethoxysilane, vinyltrimethoxysilane, tetramethoxysilane, tetraethoxysilane, phenyltrimethoxysilane, methyltriethoxysilane, octamethylcyclotetrasiloxane, dimethyldisilazane, trimethyldisilazane, tetramethyldisilazane, pentamethyldisilazane, and hexamethyldisilazane. Among these organic silicon compounds, from the viewpoints of handleability of a compound and gas barrier properties of a barrier film that is obtained, hexamethyldisiloxane and 1,1,3,3-tetramethyldisiloxane are preferable. These organic silicon compounds can be used alone or in combination of two or more kinds. Further, as the raw material gas, monosilanes other than the above-described organic silicon compounds may be contained to be used as a silicon source of the barrier film to be formed.

A reaction gas other than the raw material gas may be used as the film-forming gas. As this reaction gas, a gas that reacts with a raw material gas and becomes an inorganic compound such as an oxide and a nitride may be appropriately selected and used. As the reaction gas that forms an oxide, for example, oxygen and ozone can be used. As a reaction gas that forms a nitride, for example, nitrogen and ammonia can be used. These reaction gases can be used alone or in combination of two or more kinds. For example, when forming an oxynitride, the reaction gas that forms an oxide and the reaction gas that forms a nitride can be used in combination.

As a film-forming gas, a carrier gas may be used as necessary to supply a raw material gas to the inside of a vacuum chamber. In addition, as the film-forming gas, a gas for discharge may be used as necessary to generate discharge plasma. As the carrier gas and the gas for discharge, gases that are known may be appropriately used. For example, an inert gas such as helium, argon, neon, and xenon; and hydrogen may be used.

A pressure (degree of vacuum) inside the vacuum chamber can be appropriately adjusted in accordance with a kind of raw material gases and the like, but the pressure in the space SP is preferably 0.1 Pa to 50 Pa. Where the plasma CVD is carried out by a low-pressure plasma CVD method to suppress a vapor phase reaction, the pressure is typically 0.1 Pa to 10 Pa. In addition, electric power of an electrode drum of a plasma-generating device can be appropriately adjusted in accordance with the kind of raw material gases, the pressure inside the vacuum chamber, and the like, but the power is preferably 0.1 kW to 10 kW.

A conveying speed (line speed) of the substrate F can be appropriately adjusted in accordance with the kind of raw material gases, the pressure inside the vacuum chamber, and the like, but the conveying speed is preferably 0.1 m/min to 100 m/min, and more preferably 0.5 m/min to 20 m/min. When the line speed is less than the lower limit, wrinkles caused by heat have a tendency to occur in the substrate F. On the other hand, when the line speed exceeds the upper limit, the thickness of a barrier film that is formed has a tendency to decrease.

In the above-described manufacturing apparatus (plasma CVD film-forming device) 10, film formation is carried out with respect to the substrate F as described below.

First, it is preferable to carry out a preliminary treatment before forming a film in order for outgas generated from the substrate F to be sufficiently less. An amount of outgas generated from the substrate F can be determined using a pressure when a pressure inside of the apparatus (inside of the chamber) is reduced after the substrate F is mounted in the manufacturing apparatus. For example, if the pressure inside the chamber of the manufacturing apparatus is 1×10⁻³ Pa or less, it can be determined that the amount of outgas generated from the substrate F is sufficiently less.

Examples of a method of reducing the amount of outgas generated from the substrate F include drying methods by vacuum drying, a drying by heating, drying in combination of these methods, and natural drying. In any drying method, it is preferable to expose the entirety of the substrate F to a drying environment by repetitively carrying out rewinding (unwinding and winding) of the roll during the drying to promote drying of the inside of the substrate F wound in a roll shape.

The vacuum drying is carried out by putting the substrate F in a pressure-resistant vacuum container and evacuating the inside of the vacuum container to a vacuum state by using a pressure reducing device such as a vacuum pump. A pressure inside the vacuum container during the vacuum drying is preferably 1000 Pa or less, more preferably 100 Pa or less, and further preferably 10 Pa or less. The evacuation of the inside of the vacuum container may be continuously carried out by continuously operating the pressure reducing device, or may be intermittently carried out by intermittently operating the pressure reducing device while managing an inner pressure to be held less than a constant value. It is preferable that the drying time be at least 8 hours or more, more preferably one week or more, and still more preferably one month or more.

The drying by heating is carried out by exposing the substrate F to an environment of 50° C. or higher. A heating temperature is preferably 50° C. to 200° C., more preferably 70° C. to 150° C. At a temperature higher than 200° C., there is a concern that the substrate F may be deformed. In addition, there is a concern that an oligomer component from the substrate F may be eluted and precipitate on a surface, and thus a defect may occur. A drying time can be appropriately selected according to the heating temperature or a heating means that is used.

There is no particular limitation to the heating means as long as it is possible to heat the substrate F to a temperature of 50° C. to 200° C. under a normal pressure. Among devices that are typically known, an infrared heating device, a microwave heating device, and a heating drum are preferably used.

Here, the infrared heating device is a device that heats an object by radiating infrared rays from an infrared generating means.

The microwave heating device is a device that heats an object by irradiating microwaves from a microwave generating means.

The heating drum is a device that heats a drum surface, and brings an object into contact with the drum surface to heat the object by heat conduction from a contact portion.

The natural drying is carried out by disposing the substrate F in a low-humidity atmosphere and by ventilating a drying gas (dried air or dried nitrogen) to maintain the low-humidity atmosphere. To carry out the natural drying, it is preferable to dispose a drying agent such as silica gel in combination in the low-humidity atmosphere in which the substrate F is disposed.

It is preferable that the drying time be at least 8 hours or more, more preferably one week or more, and further preferably one month or more.

The drying may be carried out separately before mounting the substrate F in the manufacturing apparatus, or may be carried out in the manufacturing apparatus after mounting the substrate F in the manufacturing apparatus.

As a method of carrying out the drying after mounting the substrate F in the manufacturing apparatus, a method in which pressure inside of a chamber is reduced while delivering and conveying the substrate F from a delivery roll can be exemplified. In addition, a passing roll may be provided with a heater, and the heating may be carried out by heating the roll and using the roll as the above-described heating drum.

As another method of reducing the outgas from the substrate F, a method in which an inorganic film is formed in advance on a surface of the substrate F can be exemplified. Examples of the method of forming the inorganic film include physical film-forming methods such as vacuum deposition (deposition by heating), electron beam (EB) deposition, sputtering, and ion plating. The inorganic film may be formed by chemical deposition methods such as thermal CVD, plasma CVD, and atmospheric pressure CVD. Further, the substrate F in which the inorganic film is formed on a surface thereof may be further subjected to a drying treatment according to the above-described drying method to further reduce the effect from the outgas.

Next, the inside of a vacuum chamber (not shown) is set to a pressure-reduced environment, and an alternating-current voltage is applied to the film-forming roll 17 and the film-forming roll 18 to allow electric fields to be generated in the space SP.

At this time, since the above-described endless tunnel-shaped magnetic fields are formed in the magnetic field-forming devices 23 and 24, when introducing a film-forming gas, discharge plasma of a film-forming gas, which has a toroidal shape along the tunnel, is formed by the magnetic fields and electrons emitted into the space SP. The discharge plasma can be generated at a low pressure in the vicinity of several Pa, and thus a temperature inside the vacuum chamber can be set to a temperature in the vicinity of room temperature.

On the other hand, a temperature of electrons, which are regarded to be present at a high density in the magnetic fields formed by the magnetic field-forming devices 23 and 24, is high, and thus discharge plasma is generated by collision between the electrons and the film-forming gas. That is, electrons are trapped in the space SP due to the magnetic fields and electric fields that are formed in the space SP, and thus high-density discharge plasma is formed in the space SP. More specifically, high-density (high-strength) discharge plasma (first discharge plasma) is generated in a space overlapping the endless tunnel-shaped magnetic fields, and low-density (low strength) discharge plasma (second discharge plasma) is formed in a space not overlapping the endless tunnel-shaped magnetic fields. The strength of the discharge plasma continuously varies.

When the discharge plasma is generated, many radicals or ions are generated, and a plasma reaction progresses, and thus reaction between the raw material gas contained in the film-forming gas and the reaction gas occurs. For example, an organic silicon compound that is the raw material gas and oxygen that is the reaction gas react with each other, whereby an oxidation reaction of the organic silicon compound occurs.

Here, in the space in which the high-strength discharge plasma is formed, energy that can have an effect on the oxidation reaction is large. Accordingly, the reaction tends to progress, and a complete oxidation reaction of the organic silicon compound is mainly allowed to occur. On the other hand, in the space in which the low-strength discharge plasma is formed, energy that can have an effect on the oxidation reaction is small. Accordingly, the reaction is not likely to progress, and an incomplete oxidation reaction of the organic silicon compound is mainly allowed to occur.

In this specification, the “complete oxidation reaction of the organic silicon compound” represents that the reaction between the organic silicon compound and oxygen progresses and thus the organic silicon compound is oxidized and decomposed into silicon dioxide (SiO₂), water, and carbon dioxide. The “incomplete oxidation reaction of the organic silicon compound” represents that the complete oxidation reaction is not carried out for the organic silicon compound, and reaction in which SiOₓC_{y} (0<x<2, and 0<y<2) containing carbon in a structure instead of SiO₂ is generated.

As described above, since the discharge plasma is formed on the surface of the film-forming roll 17 and the film-forming roll 18 in a toroidal shape, the substrate F that is conveyed onto the surface of the film-forming roll 17 and the film-forming roll 18 alternately passes through the space in which the high-strength discharge plasma is formed and the space in which the low-strength discharge plasma is formed. Accordingly, SiO₂ that is generated by the complete oxidation reaction and SiOₓC_{y} that is generated by the incomplete oxidation reaction are alternately generated on the surface of the substrate F that passes by the surface of the film-forming roll 17 and the film-forming roll 18.

In addition to these, high-temperature secondary electrons are prevented from flowing to the substrate F due to an operation of the magnetic fields, and thus high electric power can be supplied while suppressing the temperature of the substrate F to be low. As a result, high-speed film formation is achieved. Deposition of a film mainly occurs only on a film-forming surface of the substrate F, and the film-forming roll is covered with the substrate F and is not likely to be contaminated. As a result, stable film formation for a long period of time is possible.

In the film layer H that is formed as described above, the film layer H that contains silicon, oxygen, and carbon satisfies all of the following conditions (i) to (iii) in a silicon distribution curve, an oxygen distribution curve, and a carbon distribution curve which indicate a relationship between a distance from a surface of the film layer in a thickness direction of the film layer, and a ratio of an amount of silicon atoms (atomic ratio of silicon) to a total amount of silicon atoms, oxygen atoms, and carbon atoms, a ratio of an amount of oxygen atoms (atomic ratio of oxygen) to the total amount, and a ratio of an amount of carbon atoms (atomic ratio of carbon) to the total amount, respectively.

(i) First, in the film layer H, the atomic ratio of silicon, the atomic ratio of oxygen, and the atomic ratio of carbon satisfy a condition expressed by the following expression (1) in a region of 90% or more of the thickness of the layer (more preferably, 95% or more, and particularly preferably 100%):

(atomic ratio of oxygen)>(atomic ratio of silicon)>(atomic ratio of carbon) (1), or

the atomic ratio of silicon, the atomic ratio of oxygen, and the atomic ratio of carbon satisfy a condition expressed by the following expression (2) in a region of 90% or more of the thickness of the layer (more preferably 95% or more, and particularly preferably 100%):

(atomic ratio of carbon)>(atomic ratio of silicon)>(atomic ratio of oxygen) (2).

Where the atomic ratio of silicon, the atomic ratio of oxygen, and the atomic ratio of carbon in the film layer H satisfy the condition (i), gas barrier properties of the gas barrier laminated film that may be obtained become sufficient.

(ii) Next, in the film layer H, the carbon distribution curve has at least one extremal value.

In the film layer H, it is more preferable that the carbon distribution curve have at least two extremal values, and particularly preferably at least three extremal values. Where the carbon distribution curve does not have the extremal value, the gas barrier properties become insufficient when a film of a gas barrier laminated film that is obtained is bent. As described above, when having at least three extremal values, an absolute value of a difference in a distance from a surface of the film layer H in a thickness direction of the film layer between one extremal value of the carbon distribution curve and extremal values adjacent to the extremal value is preferably 200 nm or less, and more preferably 100 nm or less.

The extremal value in 6the embodiment represents the maximum value or the minimum value of an atomic ratio of an element with respect to the distance from the surface of the film layer H in the thickness direction of the film layer H. The maximum value in this specification represents a point at which an atomic ratio value of an element varies from increase to decrease when changing the distance from the surface of the film layer H. Compared to the atomic ratio value of an element at that point, an atomic ratio value of an element at a position obtained by further changing the distance from the surface of the film layer H from that point in the thickness direction of the film layer H by 20 nm decreases by 3% by atom or more. Further, the minimum value in the embodiment represents a point at which an atomic ratio value of an element varies from decrease to increase when changing the distance from the surface of the film layer H. Compared to the atomic ratio value of an element at that point, an atomic ratio value of an element at a position obtained by further changing the distance from the surface of the film layer H from that point in the thickness direction of the film layer H by 20 nm increases by 3% by atom or more.

(iii) Further, in the film layer H, an absolute value of a difference between the maximum value and the minimum value of the atomic ratio of carbon in the carbon distribution curve is 5% by atom or more.

In the film layer H, it is preferable that the absolute value of the difference between the maximum value and the minimum value of the atomic ratio of carbon be 6% by atom or more, and more preferably 7% by atom or more. When the absolute value is less than 5% by atom, the gas barrier properties may be insufficient when a film of a gas barrier laminated film that is obtained is bent.

In the embodiment, it is preferable that the oxygen distribution curve of the film layer H have at least one extremal value, more preferably at least two extremal values, and further preferably at least three extremal values. Where the oxygen distribution curve does not have the extremal value, the gas barrier properties tend to decrease when a film of a gas barrier laminated film that is obtained is bent. As described above, in a case where the oxygen distribution curve has at least three extremal values, an absolute value of a difference in a distance from a surface of the film layer H in a thickness direction of the film layer H between one extremal value of the oxygen distribution curve and extremal values adjacent to the extremal value is preferably 200 nm or less, and more preferably 100 nm or less.

In the embodiment, it is preferable that the absolute value of the difference between the maximum value and the minimum value of the atomic ratio of oxygen in the oxygen distribution curve of the film layer H be 5% by atom or more, more preferably 6% by atom or more, and particularly preferably 7% by atom or more. When the absolute value is less than the lower limit, the gas barrier properties tend to decrease when a film of a gas barrier laminated film that is obtained is bent.

In the embodiment, it is preferable that an absolute value of a difference between the maximum value and the minimum value of an atomic ratio of silicon in the silicon distribution curve of the film layer H be less than 5% by atom, more preferably less than 4% by atom, and particularly preferably less than 3% by atom. When the absolute value exceeds the upper limit, the gas barrier properties of the obtained gas barrier laminated film tend to decrease.

In the embodiment, in an oxygen and carbon distribution curve that represents a relationship between the distance from the surface of the film layer H in the thickness direction of the film and a ratio of a total amount of oxygen atoms and carbon atoms (an atomic ratio of oxygen and carbon) to a total amount of silicon atoms, oxygen atoms, and carbon atoms, it is preferable that an absolute value of a difference between the maximum value and the minimum value of a total atomic ratio of oxygen and carbon in the oxygen and carbon distribution curve be less than 5% by atom, more preferably less than 4% by atom, and particularly preferably less than 3% by atom. When the absolute value exceeds the upper limit, gas barrier properties of a gas barrier laminated film that is obtained tends to decrease.

Here, the silicon distribution curve, the oxygen distribution curve, the carbon distribution curve, and the oxygen and carbon distribution curve can be created by so-called XPS depth profile measurement in which surface composition analysis is sequentially carried out while exposing the inside of a sample using X-ray photoelectron spectroscopy (XPS) measurement and ion sputtering of an inert gas such as argon in combination. A distribution curve that is obtained by the XPS depth profile measurement can be created, for example, by setting the vertical axis as an atomic ratio (% by atom) of each element, and by setting the horizontal axis as an etching time (sputtering time). In the element distribution curve in which the horizontal axis is set as the etching time, the etching time is approximately correlated with a distance from a surface of the film layer H in the thickness direction of the film layer H, and thus, a distance from the surface of the film layer H, which is calculated from a relationship between an etching rate and an etching time which are employed during the XPS depth profile measurement, can be employed as the “distance from the surface of the film layer H in the thickness direction of the film layer H.” As a sputtering method that is employed during the XPS depth profile measurement, it is preferable to use an inert gas ion sputtering method using argon (Ar⁺) as an etching ion species, and it is preferable to set an etching rate to 0.05 nm/sec (a value in terms of a thermally oxidized film of SiO₂).

In the embodiment, from the viewpoint of forming the film layer H having uniform and excellent gas barrier properties over the entirety of a film surface, it is preferable that the film layer H be substantially uniform in a film plane direction (a direction parallel with the surface of the film layer H). In this specification, “the film layer H is substantially uniform in the film plane direction” has a meaning as follows. In a case where the oxygen distribution curve, the carbon distribution curve, and the oxygen and carbon distribution curve are created with respect to two arbitrary measurement sites on a film plane of the film layer H by the XPS depth profile measurement, the number of extremal values of the carbon distribution curves that can be obtained at the two arbitrary measurement sites is the same in each case, and the absolute value of a difference between the maximum value and the minimum value of an atomic ratio of carbon in each of the carbon distribution curves is the same in each case or is different in a range of 5% by atom.

Further, in the embodiment, it is preferable that the carbon distribution curve be substantially continuous.

In this specification, “the carbon distribution curve is substantially continuous” represents that the carbon distribution curve does not include a portion in which an atomic ratio of carbon discontinuously varies. Specifically, in a relationship between a distance (x, unit: nm) from a surface of the film layer H, which is calculated by an etching rate and an etching time, in the thickness direction of the film layer H, and an atomic ratio of carbon (C, unit: % by atom), a condition expressed by the following mathematical expression (F1) is satisfied.

|dC/dx|≦1 (F1)

The gas barrier laminated film that is manufactured by the method of the embodiment includes at least one layer of the film layer H satisfying all of conditions (i) to (iii), but may include two or more layers satisfying the conditions. Further, in a case of including two or more layers of the film layer H, materials of a plurality of film layers H may be the same as each other or different from each other. In addition, in a case of including two or more layers of the film layer H, the film layer H may be formed on one surface of the substrate, or may be formed on both surfaces of the substrate. As the plurality of film layers H, a film layer H not having the gas barrier properties may be included.

In the silicon distribution curve, the oxygen distribution curve, and the carbon distribution curve, in a case where the atomic ratio of silicon, the atomic ratio of oxygen, and the atomic ratio of carbon satisfy a condition expressed by the expression (1) in a region of 90% or more of the thickness of the layer, it is preferable that the atomic ratio of the content of silicon atoms with respect to the total amount of silicon atoms, oxygen atoms, and carbon atoms in the film layer H be 25% by atom to 45% by atom, and more preferably 30% by atom to 40% by atom. It is preferable that the atomic ratio of the content of oxygen atoms with respect to the total amount of silicon atoms, oxygen atoms, and carbon atoms in the film layer H be 33% by atom to 67% by atom, and more preferably 45% by atom to 67% by atom. Further, it is preferable that the atomic ratio of the content of carbon atoms with respect to the total amount of silicon atoms, oxygen atoms, and carbon atoms in the film layer H be 3% by atom to 33% by atom, and more preferably 3% by atom to 25% by atom.

Further, in the silicon distribution curve, the oxygen distribution curve, and the carbon distribution curve, in a case where the atomic ratio of silicon, the atomic ratio of oxygen, and the atomic ratio of carbon satisfy a condition expressed by the expression (2) in a region of 90% or more of the thickness of the layer, it is preferable that the atomic ratio of the content of silicon atoms with respect to the total amount of silicon atoms, oxygen atoms, and carbon atoms in the film layer H be 25% by atom to 45% by atom, and more preferably 30% by atom to 40% by atom. It is preferable that the atomic ratio of the content of oxygen atoms with respect to the total amount of silicon atoms, oxygen atoms, and carbon atoms in the film layer H be 1% by atom to 33% by atom, and more preferably 10% by atom to 27% by atom. Further, it is preferable that the atomic ratio of the content of carbon atoms with respect to the total amount of silicon atoms, oxygen atoms, and carbon atoms in the film layer H be 33% by atom to 66% by atom, and more preferably 40% by atom to 57% by atom.

It is preferable that the thickness of the film layer H be in a range of 5 nm to 3000 nm, more preferably 10 nm to 2000 nm, and particularly preferably 100 nm to 1000 nm. When the thickness of the film layer H is less than the lower limit, there is a tendency that the gas barrier properties such as an oxygen gas barrier property and a water vapor barrier property deteriorate. On the other hand, when the thickness exceeds the upper limit, the gas barrier properties tend to decrease due to bending.

In a case where the gas barrier laminated film of the embodiment includes a plurality of the film layers H, a total value of the thickness of these film layers H is typically in a range of 10 nm to 10000 nm, preferably in a range of 10 nm to 5000 nm, more preferably in a range of 100 nm to 3000 nm, and particularly preferably in a range of 200 nm to 2000 nm. When the total value of the thickness of the film layers H is less than the lower limit, there is a tendency that the gas barrier properties such as an oxygen gas barrier property and a water vapor barrier property deteriorate. On the other hand, when the thickness exceeds the upper limit, the gas barrier properties tend to decrease due to bending.

When forming the film layer H, with regard to a ratio between a raw material gas and a reaction gas that are contained in a film-forming gas, it is preferable that a ratio of the reaction gas be not excessively larger than a ratio of an amount of the reaction gas that is theoretically necessary to allow the raw material gas and the reaction gas to completely react with each other. When the ratio of the reaction gas is set to be excessively large, it is difficult to obtain the film layer H satisfying all of the conditions (i) to (iii).

Hereinafter, a suitable ratio between the raw material gas and the reaction gas in the film-forming gas, and the like will be described in more detail with reference to a case of manufacturing a silicon-oxygen-based film layer using the film-forming gas, which contains hexamethyldisiloxane (HMDSO: (CH₃)₆SiO₂) as the raw material gas and oxygen (O₂) as the reaction gas, as an example.

In a case of manufacturing the silicon-oxygen-based film layer by allowing reaction to occur in the film-forming gas containing HMDSO as the raw material gas and oxygen as the reaction gas by the plasma CVD, reaction expressed by the following reaction formula (1) occurs due to the film-forming gas, and silicon dioxide is obtained.

[Chem. 1]

(CH₃)₆Si₂O+12O₂→6CO₂+9H₂O+2SiO₂ (1)

In the reaction, an amount of oxygen necessary to completely oxidize 1 mole of HMDSO is 12 moles. Therefore, when allowing complete reaction to occur by 12 moles or more of oxygen being contained with respect to 1 mole of HMDSO in the film-forming gas, a uniform silicon dioxide film is apt to be formed, and thus it is difficult to form the film layer H that satisfies all of the conditions (i) to (iii). Therefore, when forming the film layer H of the embodiment, it is necessary to set the amount of oxygen with respect to 1 mole of HMDSO to an amount less than 12 moles of a stoichiometric ratio that is a theoretical amount of oxygen necessary to completely oxidize 1 mole of HMDSO in order for the reaction of the expression (1) not to progress completely.

In a reaction inside the vacuum chamber of the manufacturing apparatus 10, since HMDSO that is a raw material and oxygen that is a reaction gas are supplied from a gas supply portion to a film-forming region and a film is formed, even when the molar amount (flow rate) of oxygen that is a reaction gas is 12 times the molar amount (flow rate) of HMDSO that is a raw material, practically, reaction is not allowed to progress in a complete manner, and thus it is considered that only when the content of oxygen is supplied in excess compared to a stoichiometric ratio is the reaction completed (for example, the molar amount (flow rate) of oxygen may be set to 20 or more times the molar amount (flow rate) of HMDSO that is a raw material to obtain a silicon oxide by carrying out complete oxidation by CVD). Accordingly, it is preferable that the molar amount (flow rate) of oxygen with respect to the molar amount (flow rate) of HMDSO that is a raw material be set to 12 or less times (more preferably, 10 or less times), 12 times being a stoichiometric ratio.

When HMDSO and oxygen are contained at this ratio, carbon atoms or hydrogen atoms in HMDSO that are incompletely oxidized are taken into the film layer H, and it is possible to form the film layer H that satisfies all of the conditions (i) to (iii). As a result, a gas barrier laminated film that is obtained can exhibit excellent barrier properties and bending resistance.

If the molar amount (flow rate) of oxygen with respect to the molar amount (flow rate) of HMDSO in the film-forming gas is too small, carbon atoms or hydrogen atoms that are not oxidized are excessively taken into the film layer H, and thus transparency of the barrier film decreases in this case. This gas barrier film cannot be used in a flexible substrate for a device such as an organic EL device and an organic film solar cell in which transparency is necessary. From this viewpoint, it is preferable that the lower limit of the molar amount (flow rate) of oxygen with respect to the molar amount (flow rate) of HMDSO in the film-forming gas be set to an amount more than 0.1 times the molar amount (flow rate) of HMDSO, and more preferably more than 0.5 times.

Whether or not the organic silicon compound is completely oxidized as described above can also be controlled by an application voltage that is applied to the film-forming roll 17 and the film-forming roll 18 in addition to the mixing ratio of the raw material gas and the reaction gas in the film-forming gas.

Formation of a film layer can be carried out with respect to a surface of the substrate F that is wound around the film-forming roll 17 and the film-forming roll 18 by the plasma CVD method using the discharge plasma.

(Configuration Example of Film Layer)

With regard to the laminated film that is formed as described above, in at least one layer of the film layer, an electron beam transmittance curve, which represents a relationship between a distance from a surface of the layer in a thickness direction of the layer and an electron beam transmittance, may have at least one extremal value. In a case where the electron beam transmittance curve has at least one extremal value, sufficiently high gas barrier properties can be achieved by the film layer, and even when the film is bent, a decrease in the gas barrier properties can be sufficiently suppressed.

As the film layer, from the viewpoints of obtaining a relatively greater effect, it is more preferable that the electron beam transmittance curve have at least two extremal values, and particular preferably at least three extremal values. As described above, in a case of having at least three extremal values, an absolute value of a difference in a distance from a surface of the film layer in a thickness direction of the film layer between one extremal value of the electron beam transmittance curve and extremal values adjacent to the extremal value is preferably 200 nm or less, and more preferably 100 nm or less. The extremal value in the embodiment represents the maximum value or the minimum value of a curve (electron beam transmittance curve) obtained by plotting the magnitude of the electron beam transmittance with respect to the distance from the surface of the film layer in the thickness direction of the film layer. In the embodiment, whether or not the extremal value (the maximum value or the minimum value) of the electron beam transmittance curve is present may be determined by the following method of determining whether or not the extremal value is present.

The electron beam transmittance in the embodiment represents a transmission degree of the electron beams through a film layer forming material at a predetermined position in the film layer. As a method of measuring the electron beam transmittance, various known methods can be employed. For example, (i) a method of measuring the electron beam transmittance using a transmission electron microscope, and (ii) a method of measuring the electron beam transmittance by measuring secondary electrons or reflection electrons using a scanning electron microscope can be employed.

Hereinafter, the method of measuring the electron beam transmittance and the method of measuring the electron beam transmittance curve will be described with reference to a case of using the transmission electron microscope as an example.

In the method of measuring the electron beam transmittance in the case of using the transmission electron microscope, first, a thin-piece sample is prepared by cutting a substrate including a film layer in a direction perpendicular to a surface of the film layer. Next, a transmission electron microscope image of the surface (plane perpendicular to the surface of the film layer) of the sample is obtained using the transmission electron microscope. Then, the transmission electron microscope image is measured in this manner, and the electron beam transmittance at each position of the film can be obtained on the basis of contrast at each position on the image.

Here, in a case of observing the thin-piece sample obtained by cutting the substrate including the film layer in a direction perpendicular to the surface of the film layer using the transmission electron microscope, contrast at each position of the transmission electron microscope image represents a variation in the electron transmittance of the material at each position. To allow the contrast to correspond to the electron beam transmittance, it is preferable to secure contrast suitable for the transmission electron microscope image, and it is preferable to appropriately select observation conditions such as a thickness of the sample (thickness in a direction parallel with the surface of the film layer), an acceleration voltage, and a diameter of an objective aperture.

It is preferable that the thickness of the sample be 10 nm to 300 nm, more preferably 20 nm to 200 nm, further preferably 50 nm to 200 nm, and particularly preferably 100 nm.

It is preferable that the acceleration voltage be 50 kV to 500 kV, more preferably 100 kV to 300 kV, further preferably 150 kV to 250 kV, and particularly preferably 200 kV.

It is preferable that the diameter of the objective aperture be 5 μm to 800 μm, more preferably 10 μm to 200 μm, and particularly preferably 160 μm.

As the transmission electron microscope, it is preferable to use a microscope having sufficient resolution with respect to the transmission microscope image. It is preferable that the resolution be at least 10 nm or less, more preferably 5 nm or less, and particularly preferably 3 nm or less.

In the method of measuring the electron beam transmittance, to obtain the electron beam transmittance at each position of the film on the basis of contrast at each position on the image, the transmission electron microscope image (contrast image) is repetitively divided into a constant unit region, and a cross-section contrast variable (C) that corresponds to the contrast of each unit region is applied to the unit region. Typically, this image processing can be easily carried out by electronic image processing using a computer.

In the image processing, first, it is preferable to cut an arbitrary region that is suitable for analysis from the contrast image that is obtained.

It is necessary for the contrast image cut in this manner to include at least a portion from one surface of the film layer and a portion up to another surface which is opposite to the portion. The contrast image may include a layer that is adjacent to the film layer. As the layer adjacent to the film layer as described above, a substrate and a protective layer that is necessary for carrying out observation to obtain the contrast image can be exemplified.

It is necessary for a cross-section (reference plane) of the contrast image cut in this manner to be parallel with the surface of the film layer. It is preferable that the contrast image cut in this manner have a trapezoidal shape or parallelogram shape which is surrounded by two sides that are opposite to each other perpendicularly to a direction (thickness direction) perpendicular to at least the surface of the film layer, and it is more preferable that the contrast image have a rectangular shape formed by the two sides and two sides that are perpendicular to these sides (that are parallel with the thickness direction).

The contrast image that is cut in this manner are repetitively divided into constant unit regions, but as a division method, for example, a method of dividing the contrast image with a lattice-shaped partition can be employed. In this case, each of the unit regions that are divided with the lattice-shaped partition constitutes one pixel. It is preferable that this contrast image pixel be as fine as possible to reduce an error. However, as the pixel becomes finer, there is a tendency that a time necessary for analysis increases. Therefore, it is preferable that the length of one side of the contrast image pixel be 10 nm or less in terms of actual dimensions of the sample, more preferably 5 nm or less, and particularly preferably 3 nm or less.

The cross-section contrast variable (C) that is applied as described above is a value obtained by converting a degree of the contrast of each region into numerical information. The converting method into the cross-section contrast variable (C) is not particularly limited, but for example, setting (256-grayscale setting) can be carried out in such a manner that the densest unit region is set as 0, the lightest unit region is set as 255, and an integer from 0 to 255 is applied in accordance with the degree of the contrast of each unit region. Here, it is preferable to set the numerical values in such a manner that a numerical value of a portion at which the electron beam transmittance is high increases.

Then, from the cross-section contrast variable (C), a contrast variable (CZ) in a thickness direction at a distance (z) from the reference plane in a thickness direction of the film layer can be calculated by the following method. That is, an average value of the cross-section contrast variable (C) of a unit region at which the distance (z) from the reference plane in the thickness direction of the film layer becomes a predetermined value is calculated to obtain the contrast variable (CZ) in a thickness direction.

It is preferable that the average value of the cross-section contrast variable (C) stated here be an average value of a cross-section contrast variable (C) of a unit region of arbitrary 100 points or more at which the distance (z) from the reference plane becomes a predetermined value (same value). In addition, as described above, in a case of obtaining the contrast variable (CZ) in the thickness direction, it is preferable to appropriately carry out noise removal processing for removing noise.

As the noise removal processing, a moving average method, interpolation, and the like can be employed. Examples of the moving average method include a simple moving average method, a weighted moving average method, an index-smoothing moving average method, and the like, but it is preferable to employ the simple moving average method. When using the simple moving average method, it is preferable to appropriately select an averaging range in such a manner that the averaging range is sufficiently smaller than a typical size of a structure in the thickness direction of the film layer, and data that is obtained becomes sufficiently smooth. Examples of the interpolation include spline interpolation, Lagrange interpolation, linear interpolation, and the like, but it is preferable to employ the spline interpolation and Lagrange interpolation.

A region, at which a variation of the contrast variable (CZ) in the thickness direction with respect to a position in the thickness direction is gentle, occurs in the vicinity of both interfaces of the film layer by the noise removal processing (the region is referred to as a transition region). It is preferable to remove the transition region from an extremal value determination region of the electron beam transmittance curve of the film layer from the viewpoint of clarifying a reference during the following determination on whether or not the extremal value of the electron beam transmittance curve is present.

As a main cause of the occurrence of the transition region, non-planarity of the film interface, the above-described noise removal processing, and the like can be considered. Accordingly, the transition region may be removed from the determination region of the electron beam transmittance curve by employing the following method.

That is, first, a position at a distance (z) from the reference plane in the thickness direction of the film layer, at which an absolute value |dCZ/dz| of a gradient in the vicinity of the both interfaces of the film layer becomes the largest, is set as a temporary interface position.

Next, the absolute value of the gradient (dCZ/dz) is confirmed sequentially from an outer side of the temporary interface position toward an inner side (film layer side), and a position at a distance (z) (when assuming a graph in which the vertical axis represents the absolute value of dCZ/dz and the horizontal axis represents the distance (z) from the reference plane, a distance (z) at a portion at which the absolute value of dCZ/dz is below 0.1 nm⁻¹ for the first time when the graph is traced from the distance (z) on an outer side of the temporary interface position toward an inner side (film layer side)) from the reference plane in the thickness direction of the film layer at a position at which the absolute value becomes 0.1 nm⁻¹ (in the case of 256-grayscale setting) is set as an interface of the film.

Then, the transition region can be removed from the determination region by removing a region on an outer side of the interface from the determination region of the electron beam transmittance curve of the film layer. When obtaining the contrast variable (CZ) in the thickness direction as described above, it is preferable to carry out standardization in such a manner that the average value of the contrast variable (CZ) in the thickness direction in a range corresponding to the film layer becomes 1.

The contrast variable (CZ) in the thickness direction which is calculated as described above is proportional to the electron beam transmittance (T). Accordingly, the electron beam transmittance curve can be created by expressing the contrast variable (CZ) in the thickness direction with respect to the distance (z) from the reference plane in the thickness direction of the film layer. That is, the electron beam transmittance curve can be obtained by plotting the contrast variable (CZ) in the thickness direction with respect to the distance (z) from the reference plane in the thickness direction of the film layer. A variation in a gradient (dT/dz) of the electron beam transmittance (T) can be also known by calculating a gradient (dCZ/dz) obtained by differentiating the contrast variable (CZ) in the thickness direction with the distance (z) from the reference plane in the thickness direction of the film layer.

In the electron beam transmittance curve that is obtained in this manner, whether or not the extremal value is present can be determined as follows. That is, where the electron beam transmittance curve has the extremal value (the maximum value or the minimum value), the maximum value of the gradient (dCZ/dz) of a contrast coefficient in the thickness direction becomes a positive value, the minimum value of the gradient (dCZ/dz) becomes a negative value, and an absolute value of a difference between the maximum value and the minimum value increases. On the contrary, where the extremal value is not present, both of the maximum value and the minimum value of the gradient (dCZ/dz) become a positive value or a negative value, and thus the absolute value of a difference between the maximum value and the minimum value decreases. Accordingly, when determining whether or not the extremal value is present, it is possible to determine whether or not the extremal value is present by determining whether or not both of the maximum value and the minimum value of the gradient (dCZ/dz) become a positive value or a negative value, and it is possible to determine whether or not the electron beam transmittance curve has the extremal value on the basis of the magnitude of the absolute value of the difference between the maximum value (dCZ/dz) MAX and the minimum value (dCZ/dz) MIN of the gradient (dCZ/dz).

Where the extremal value is not present, the contrast variable (CZ) in the thickness direction always shows 1 that is standardized average value. However, practically, a signal includes a slight noise in many cases, and thus the electron beam transmittance curve fluctuates due to noise at a value close to the standardized average value of 1. Accordingly, when determining whether or not the extremal value is present in the electron beam transmittance curve, when determining the extremal value on the basis of only the viewpoint whether or not the maximum value and the minimum value of the gradient of the electron beam transmittance curve are a positive value or a negative value, or the viewpoint of the absolute value of the difference between the maximum value and the minimum value of the gradient of the electron beam transmittance curve, it may be determined that the extremal value is present in the electron beam transmittance curve due to the noise.

Therefore, when determining whether or not the extremal value is present, the fluctuation due to the noise and the extremal value are distinguished according to the following reference. Specifically, when setting a point, at which the signs of the gradient (dCZ/dz) of the contrast variable (CZ) in the thickness direction are reversed from each other with zero set as a reference, as a temporary extremal value point, in a case where an absolute value of a difference between a contrast variable (CZ) in the thickness direction at the temporary extremal value point and a contrast variable (CZ) in the thickness direction at an adjacent temporary extremal value point (when two adjacent temporary extremal value points are present, a point at which the absolute value of the difference is larger is selected) is 0.03 or more, the temporary extremal value point can be determined as a point having the extremal value. In other words, where the absolute value of the difference between the contrast variable (CZ) in the thickness direction at the temporary extremal value point and the contrast variable (CZ) in the thickness direction at the adjacent temporary extremal value point (when two adjacent temporary extremal value points are present, a point at which the absolute value of the difference is larger is selected) is less than 0.03, the temporary extremal value point can be determined as noise.

In addition, in a case where only one temporary extremal value point is present, a method of carrying out the following determination may be employed. That is, in a case in which an absolute value of a difference between the contrast variable (CZ) in the thickness direction and the standardized average value of 1 is as large as 0.03 or more, the temporary extremal value point is determined as an extremal value not noise. The numerical value of “0.03” is a numerical value obtained when standardizing the magnitude of the numerical value of the contrast variable (CZ) in the thickness direction by setting the average value of the contrast variable (CZ) in the thickness direction which is obtained by the above-described 256-grayscale setting to 1 (a numerical value “0” of the contrast variable in the thickness direction which is obtained by the 256-grayscale setting during standardization is set to “0” as is).

The laminated film that is a target of the embodiment may be set in such a manner that at least one layer of film layer have at least one extremal value in the electron beam transmittance curve. The film layer having at least one of extremal value in the electron beam transmittance curve is referred to as a layer in which a composition varies in the thickness direction. Due to the laminated film including the film layer, it is possible to achieve sufficiently high gas barrier properties and it is possible to sufficiently suppress a decrease in gas barrier properties when the film is bent.

It is preferable that the electron beam transmittance curve be substantially continuous. In this specification, the phrase “electron beam transmittance curve is substantially continuous” represents that the electron beam transmittance curve does not include a portion in which the electron beam transmittance discontinuously varies. Specifically, the phrase represents that the absolute value of the gradient (dCZ/dz) of the contrast variable (CZ) in the thickness direction is equal to or less than a predetermined value, and preferably 5.0×10⁻²/nm or less.

In the embodiment, from the viewpoint of forming the film layer having uniform and excellent gas barrier properties over the entirety of film surface, it is preferable that the film layer be substantially uniform in a film plane direction (a direction parallel with the surface of the film layer). In this specification, the phrase “film layer is substantially uniform in the film plane direction” has a meaning as follows. Even when the electron beam transmittance curve is created by measuring the electron beam transmittance in arbitrary sites on the film plane of the film layer, the number of extremal values of the electron beam transmittance curve that is obtained is the same in each case. Even when samples for measurement of two arbitrary points are cut from the film plane of the film layer and the electron beam transmittance curves of the respective samples are created, where the number of the extremal values of the electron beam transmittance curve in all of the samples are the same as each other, it can be assumed that the film layer is substantially uniform.

For example, the laminated film of the embodiment can be manufactured as described above.

When ²⁹Si solid-state NMR measurement of the film layer H is carried out with respect to the laminated film manufactured as described above, and a ratio of a total value of Q¹, Q², and Q³ peak areas to a Q⁴ peak area satisfies the conditional expression (I), the laminated film has high gas barrier properties.

As one index for evaluating the gas barrier properties of the laminated film of the invention, as described above, the water vapor permeability is exemplified, but the water vapor permeability of the laminated film of the invention can be measured, for example, according to a measurement method described in Example. With regard to the water vapor permeability of the laminated film of the invention, for example, under conditions of a temperature of 40° C., and humidity of 0% RH on a low humidity side and humidity of 90% RH on a high humidity side, the water vapor permeability is preferably 10⁻⁵ g/(m²·day) or less, and more preferably 10⁻⁶ g/(m²·day) or less.

For example, as illustrated in the above-described manufacturing method, when manufacturing a laminated film in which the film layer H is formed with respect to the long substrate F, test specimens are prepared as representative samples at regular intervals in the longitudinal direction, and the solid-state NMR of the test specimens is measured. From the measurement, it can be confirmed that the laminated film satisfies the conditional expression (I).

According to the laminated film configured as described above, the laminated film can have high gas barrier properties.

FIG. 6 shows a side cross-sectional diagram illustrating a configuration example of an organic electroluminescence (organic EL) device that is an electronic device of the embodiment.

The organic EL device related to the embodiment can be applied to various electronic apparatuses that use light. The organic EL device of the embodiment may be, for example, a part of a display unit of a portable apparatus and the like, or a part of an image-forming device such as a printer. The organic EL device of the embodiment may be, for example, a light source (backlight) of a liquid crystal display panel and the like, or a light source of an illumination apparatus.

The organic EL device 50 shown in FIG. 6 includes a pair of electrodes (a first electrode 52 and a second electrode 53), a light-emitting layer 54, a laminated film (a first substrate) 55, a laminated film (a second substrate) 56, and a sealing material 65. The above-described laminated film of the invention is used for the laminated films 55 and 56. The laminated film 55 includes a substrate 57 and a barrier film 58. The laminated film 56 includes a substrate 59 and a barrier film 60.

The light-emitting layer 54 is disposed between the first electrode 52 and the second electrode 53. The first electrode 52, the second electrode 53, and the light-emitting layer 54 constitute an organic EL element (functional element). The laminated film 55 is disposed on a side opposite to the light-emitting layer 54 with the first electrode 52 made as a reference. The laminated film 56 is disposed on a side opposite to the light-emitting layer 54 with the second electrode 53 made as a reference. Further, the laminated film 55 and the laminated film 56 are bonded to each other by a sealing material 65 disposed to surround the periphery of the organic EL element, and form a sealing structure in which the organic EL element is sealed.

In the organic EL device 50, when electric power is supplied between the first electrode 52 and the second electrode 53, carriers (electrons and holes) are supplied to the light-emitting layer 54, and thus light occurs in the light-emitting layer 54. An electric power supply source with respect to the organic EL device 50 may be mounted on the same device together with the organic EL device 50, or may be provided at the outside of the device. Light emitted from the light-emitting layer 54 is used for display or formation of an image, illumination and the like in accordance with a use of a device including the organic EL device 50, and the like.

In the organic EL device 50 of the embodiment, as forming materials (organic EL forming materials) of the first electrode 52, the second electrode 53, and the light-emitting layer 54, materials that are typically known are used. Generally, it is known that the organic EL device forming materials easily deteriorate by moisture or oxygen. However, in the organic EL device 50 of the embodiment, the organic EL element is sealed by the sealing structure surrounded by the laminated film 55 and the laminated film 56 of the invention, which have high gas barrier properties, and the sealing material 65. Accordingly, the organic EL device 50 in which deterioration of performance is less and thus reliability is high can be obtained.

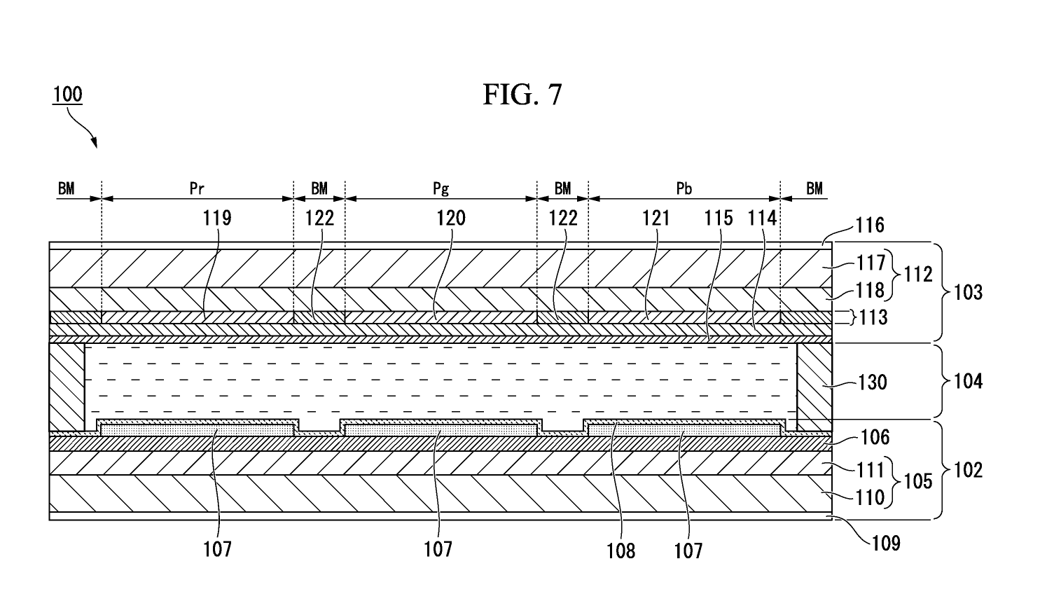

FIG. 7 shows a side cross-sectional diagram of a liquid crystal display device that is an electronic device related to the embodiment.

The liquid crystal display device 100 shown in the drawing includes a first substrate 102, a second substrate 103, and a liquid crystal layer 104. The first substrate 102 is disposed to face the second substrate 103. The liquid crystal layer 104 is disposed between the first substrate 102 and the second substrate 103. For example, the liquid crystal display device 100 is manufactured by bonding the first substrate 102 and the second substrate 103 using a sealing material 130, and by enclosing the liquid crystal layer 104 in a space surrounded by the first substrate 102, the second substrate 103, and the sealing material 130.

The liquid crystal display device 100 may include a plurality of pixels. The plurality of pixels is arranged in a matrix shape. The liquid crystal display device 100 of the embodiment is capable of displaying full color images. Each pixel of the liquid crystal display device 100 includes a sub-pixel Pr, a sub-pixel Pg, and a sub-pixel Pb. A light-shielding region BM is formed between the sub-pixels. Each of the three kinds of sub-pixels emits colored light having a different grayscale corresponding to an image signal toward an image display side. In the embodiment, red light is emitted from the sub-pixel Pr, green light is emitted from the sub-pixel Pg, and blue light is emitted from the sub-pixel Pb. The three colors of colored light, which are emitted from the three kinds of sub-pixels, are mixed together and visually recognized, whereby one full-color pixel is displayed.

The first substrate 102 includes a laminated film (first substrate) 105, an element layer 106, a plurality of pixel electrodes 107, an orientation film 108, and a polarization plate 109. Each of the pixel electrodes 107 constitutes a pair of electrodes in combination with a common electrode 114 to be described later. The laminated film 105 includes a substrate 110 and a barrier film 111. The substrate 110 has a thin sheet shape or a film shape. The barrier film 111 is formed on one surface of the substrate 110. The element layer 106 is laminated and formed over the substrate 110 on which the barrier film 111 is formed. Each of the plurality of pixel electrodes 107 is formed on the element layer 106 independently for each sub-pixel of the liquid crystal display device 100. The orientation film 108 is provided on the pixel electrodes 107 and between the pixel electrodes 107 across the plurality of sub-pixels.

The second substrate 103 includes a laminated film (second substrate) 112, a color filter 113, a common electrode 114, an orientation film 115, and a polarization plate 116. The laminated film 112 includes a substrate 117 and a barrier film 118. The substrate 117 has a thin sheet shape or a film shape. The barrier film 118 is formed on one surface of the substrate 117. The color filter 113 is laminated and formed over the substrate 110 on which the barrier film 111 is formed. The common electrode 114 is provided on the color filter 113. The orientation film 115 is formed on the common electrode 114.

The first substrate 102 and the second substrate 103 are disposed to face each other in such a manner that the pixel electrode 107 and the common electrode 114 face each other, and are bonded to each other with the liquid crystal layer 104 interposed therebetween. The pixel electrode 107, the common electrode 114, and the liquid crystal layer 104 form a liquid crystal display element (functional element). Further, the laminated film 105 and the laminated film 112 form a sealing structure in which the liquid crystal display element is sealed in combination with the sealing material 130 disposed to surround the periphery of the liquid crystal display element.

In the liquid crystal display device 100, since the laminated film 105 and the laminated film 112 of the invention, which have high gas barrier properties, form a part of the sealing structure in which the liquid crystal display element is sealed, the liquid crystal display device 100 in which there is less concern that the liquid crystal display element deteriorates due to oxygen or moisture in the air and performance thereof decreases, and thus reliability is high can be obtained.

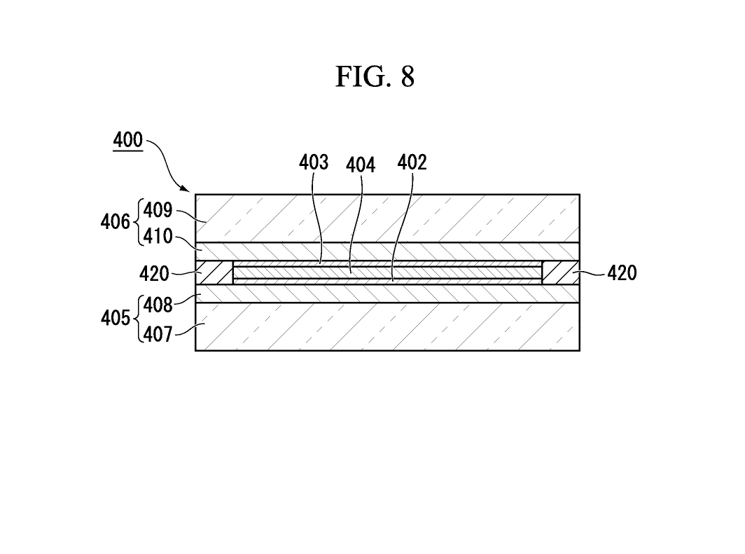

FIG. 8 shows a side cross-sectional diagram of a photoelectric conversion device that is an electronic device of the embodiment. The photoelectric conversion device of the embodiment can be used in various devices such as a light detection sensor and a solar cell which convert light energy to electric energy, and the like.

The photoelectric conversion device 400 shown in the drawing include a pair of electrodes (a first electrode 402 and a second electrode 403), a photoelectric conversion layer 404, a laminated film (first substrate) 405, and a laminated film (second substrate) 406. The laminated film 405 includes a substrate 407 and a barrier film 408. The laminated film 406 includes a substrate 409 and a barrier film 410. The photoelectric conversion layer 404 is disposed between the first electrode 402 and the second electrode 403. The first electrode 402, the second electrode 403, and the photoelectric conversion layer 404 form a photoelectric conversion element (functional element).

The laminated film 405 is disposed on a side opposite to the photoelectric conversion layer 404 with the first electrode 402 made as a reference. The laminated film 406 is disposed on a side opposite to the photoelectric conversion layer 404 with the second electrode 403 made as a reference. Further, the laminated film 405 and the laminated film 406 are bonded to each other by a sealing material 420 disposed to surround the periphery of the photoelectric conversion element, and form a sealing structure in which the photoelectric conversion element is sealed.

In the photoelectric conversion device 400, the first electrode 402 is a transparent electrode, and the second electrode 403 is a reflective electrode. In the photoelectric conversion device 400 of this example, light energy of light that is incident to the photoelectric conversion layer 404 through the first electrode 402 is converted to electric energy by the photoelectric conversion layer 404. The electric energy is taken to the outside of the photoelectric conversion device 400 through the first electrode 402 and the second electrode 403. Material and the like of respective components that are disposed on a light path of light that is incident to the photoelectric conversion layer 404 from the outside of the photoelectric conversion device 400 are appropriately selected in order for portions corresponding to at least the light path to have translucency. Components that are disposed at portions other than the light path of light from the photoelectric conversion layer 404 may be formed from a translucent material or material that shields a part or the entirety of the light.

In the photoelectric conversion device 400 of the embodiment, typically known materials are used for the first electrode 402, the second electrode 403, and the photoelectric conversion layer 404. In the photoelectric conversion device 400 of the embodiment, the photoelectric conversion element is sealed by a sealing structure surrounded by the laminated films 405 and 406 of the invention which have high gas barrier properties, and the sealing material 420. Accordingly, the photoelectric conversion device 400 in which there is less concern that the photoelectric conversion layer and the electrodes deteriorate due to oxygen or moisture in the air and performance decreases, and thus reliability is high can be obtained.

Hereinbefore, a very preferred embodiment of the invention has been described with reference to the attached drawings, but it is needless to say that the invention is not limited to the embodiment. The shapes, combinations, and the like of the respective constituent members that are shown in the above-described embodiment are illustrative only, and various modifications can be made on the basis of design requirements and the like in a range not departing from the scope of the invention.

### EXAMPLES

Hereinafter, the invention will be described in more detail on the basis of an example and comparative examples, but the invention is not limited to the following example. The water vapor permeability of the laminated film and the ²⁹Si solid-state NMR spectrum of the barrier film of the laminated film were measured by the following method.

(i) Measurement of Water Vapor Permeability of Laminated Film

The water vapor permeability of the laminated film was measured under conditions of a temperature of 40° C., and humidity of 0% RH on a low humidity side and humidity of 90% RH on a high humidity side using a water vapor permeability measuring device (model name: GTR-3000, manufactured by GTR Tec Corporation) according to Annex C “method of obtaining water vapor permeability according to a gas chromatography method” of JIS K 7129: 2008 “Plastics-Film and Sheet—method of obtaining water vapor permeability (an apparatus measuring method).”

(ii) Measurement ²⁹Si Solid-State NMR Spectrum

The ²⁹Si solid-state NMR spectrum was measured using ²⁹Si-NMR (AVANCE 300, manufactured by BRUKER). Detailed measurement conditions were as follows (a cumulated number: 49152 times, relaxation time: 5 seconds, a resonant frequency: 59.5815676 MHz, MAS rotation: 3 kHz, and CP method).

Peak areas of ²⁹Si solid-state NMR were calculated as follows. It was known in advance that either a Q³ silicon atom or a Q⁴ silicon atom was contained in the film layer that was a target to be measured in this example and a Q¹ silicon atom or a Q² silicon atom was not contained.

First, the spectrum that was obtained by the ²⁹Si solid-state NMR measurement was subjected to smoothing processing. In the following description, a spectrum after the smoothing was referred to as a “measurement spectrum.”

Next, the measurement spectrum was separated into a Q³ peak and a Q⁴ peak. That is, parameters such as the height and half-value width of each of the peaks were optimized in order for a model spectrum obtained by adding up Q³ and Q⁴ to coincide with the measurement spectrum after the smoothing on the assumption that the Q³ peak and the Q⁴ peak exhibited Gauss distribution (normal distribution) curves centering around intrinsic chemical shifts (Q³: −102 ppm, Q⁴: −112 ppm), respectively.

The parameter optimization was carried out using an iteration method, and calculation was carried out so that the sum of squares of differences between the model spectrum and the measurement spectrum converged to the minimum value.

Next, areas of portions surrounded by a baseline and the Q³ peak and the Q⁴ peak which were obtained in this manner were obtained by integration, respectively, and were calculated as a Q³ peak area and a Q⁴ peak area. Further, (Q³ peak area)/(Q⁴ peak area) was obtained using the calculated peak areas, and confirmation on a relationship between a value of (Q³ peak area)/(Q⁴ peak area) and the gas barrier properties was carried out.

### Example 1

A laminated film was manufactured by the above-described manufacturing apparatus shown in FIG. 2.

That is, a biaxially stretched polyethylenenaphthalate film (PEN film, thickness: 100 μm, width: 700 mm, product name: “Teonex Q65FA”, manufactured by Teijin DuPont Films Japan Limited) was used as a substrate (substrate F), and this film was mounted on the delivery roll 11. Then, endless tunnel-shaped magnetic fields were formed in a space between the film-forming roll 17 and the film-forming roll 18, and electric power was supplied to each of the film-forming roll 17 and the film-forming roll 18 to generate discharge plasma between the film-forming roll 17 and the film-forming roll 18. A film-forming gas (mixed gas of hexamethyldisiloxane (HMDSO) as a raw material gas and oxygen gas (also functions as a discharge gas) as a reaction gas) was supplied to the discharge region to carry out film formation according to the plasma CVD method under the following conditions. This process was carried out three times, whereby the laminated film of Example 1 was obtained.

<Film-Forming Condition>

Mixing ratio (hexamethyldisiloxane/oxygen) of the film-forming gas: 100/1000 [unit: sccm (Standard Cubic Centimeter per Minute)]

Degree of vacuum inside the vacuum chamber: 3 Pa

Electric power applied from a power supply for plasma generation: 1.6 kW

Frequency of the power supply for plasma generation: 70 kHz

Film conveying speed: 0.5 m/min

To sufficiently reduce outgas from the substrate film, the substrate film was mounted on the delivery roll of the manufacturing apparatus on the day before the film formation, and was left as is in a vacuum state to sufficiently dry the substrate film. The degree of vacuum before the film formation was 5×10⁻⁴ Pa or less. The thickness of the barrier film of the laminated film that was obtained by the film formation was 1.02 μm, and the water vapor permeability under conditions of a temperature of 40° C., and humidity of 0% RH on a low humidity side and humidity of 90% RH on a high humidity side was 2×10⁻⁵ g/(m²·day).

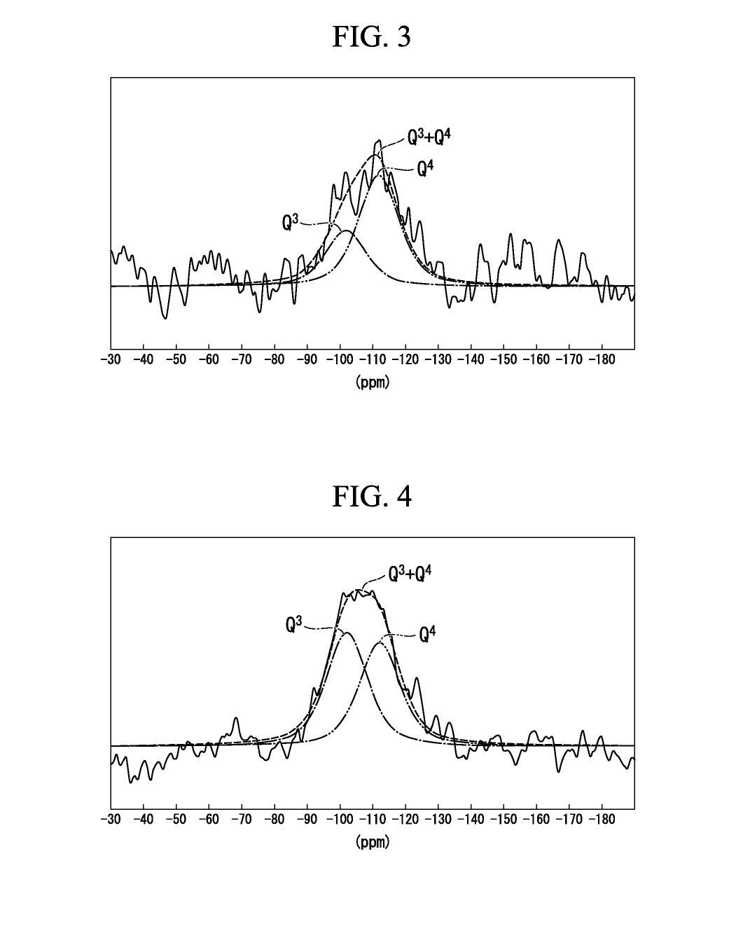

Spectra were measured using ²⁹Si solid-state NMR to calculate a ratio of Q³/Q⁴ in the barrier film. A sample was obtained by cutting the barrier film-attached substrate to pieces using scissors. The obtained spectra are shown in FIG. 3. Peak areas standardized by the Q⁴ peak area are shown in Table 1.

TABLE 1

| Chemical shift (ppm) | Belongingness | Integration ratio |
|---|---|---|
| −102.0 | Q³ | 0.51 |
| −112.0 | Q⁴ | 1.00 |

As shown in Table 1, with regard to the obtained spectra, an area ratio between Q³ and Q⁴ was calculated to obtain a ratio of Q³/Q⁴. From the calculation, Q³/Q⁴ was 0.51.

### Comparative Example 1

The substrate film was mounted on the delivery roll of the manufacturing apparatus on the day of the film formation, and was left as is for one hour in a vacuum state. Then, the film formation was carried out. The degree of vacuum before the film formation was approximately 3×10⁻³ Pa, and it was in a state in which the outgas was continuously emitted from the substrate. The laminated film was manufactured by the same method as Example 1 except that the degree of vacuum inside the manufacturing apparatus before the film formation was different.

The thickness of the barrier film of the obtained laminated film was 1.09 μm, and the water vapor permeability under conditions of a temperature of 40° C., and humidity of 0% RH on a low humidity side and humidity of 90% RH on a high humidity side was 2×10⁻³ g/(m²·day).

Spectra were measured using ²⁹Si solid-state NMR to calculate a ratio of Q³/Q⁴ in the barrier film. A sample was obtained by cutting the barrier film-attached substrate to pieces using scissors. The obtained spectra are shown in FIG. 4. Peak areas standardized by the Q⁴ peak area are shown in Table 2.

TABLE 2

| Chemical shift (ppm) | Belongingness | Integration ratio |
|---|---|---|
| −102.0 | Q³ | 1.10 |
| −112.0 | Q⁴ | 1.00 |

As shown in Table 2, with regard to the obtained spectra, an area ratio between Q³ and Q⁴ was calculated to obtain a ratio of Q³/Q⁴. From the calculation, Q³/Q⁴ was 1.10.

### Comparative Example 2

A laminated film of Comparative Example 2 was obtained in the same manner as Example 1 except that a biaxially stretched polyethylenenaphthalate film (PEN film, thickness: 100 μm, width: 350 mm, product name: “Teonex Q65FA”, manufactured by Teijin DuPont Films Japan Limited) was used as a substrate (substrate F), and the film formation according to the plasma CVD method was carried out under the following conditions.

<Film Formation Condition>

Mixing ratio (hexamethyldisiloxane/oxygen) of the film-forming gas: 50/500 [unit: sccm (Standard Cubic Centimeter per Minute)]

Degree of vacuum inside the vacuum chamber: 3 Pa

Electric power applied from a power supply for plasma generation: 0.8 kW

Frequency of the power supply for plasma generation: 70 kHz

Film conveying speed: 0.5 m/min

The substrate film was mounted on the delivery roll of the manufacturing apparatus, and then the laminated film was manufactured without sufficiently taking the time of drying the substrate film in a vacuum state similar to Comparative Example 1. The thickness of the barrier film of the laminated film that was obtained by the film formation was 1.23 μm, and the water vapor permeability under conditions of a temperature of 40° C., and humidity of 0% RH on a low humidity side and humidity of 6 90% RH on a high humidity side was 1.4×10⁻³ g/(m²·day).

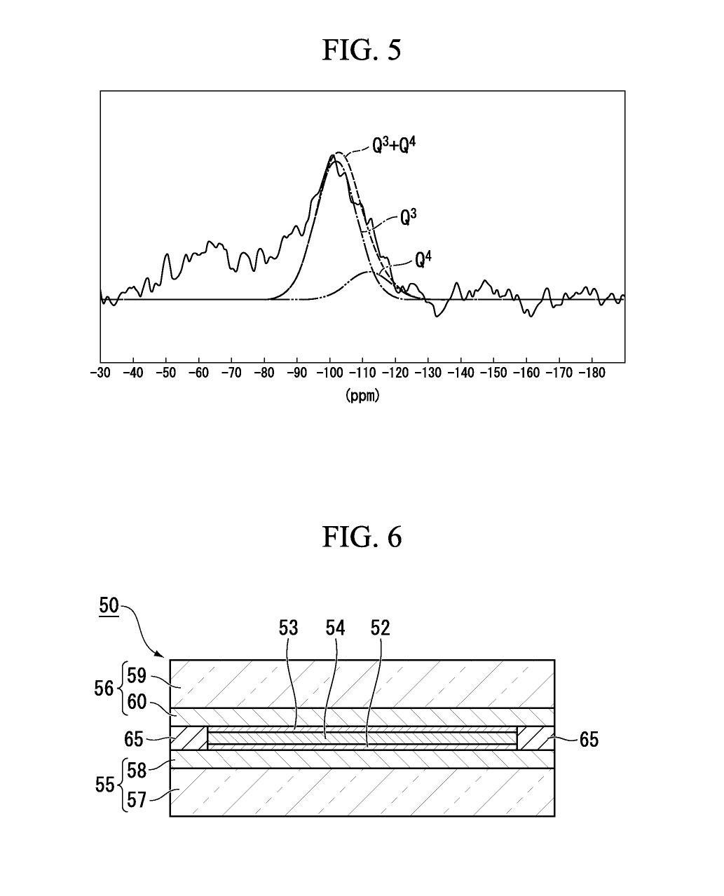

Spectra were measured using ²⁹Si solid-state NMR to investigate a ratio of Q³/Q⁴ in the barrier film. A sample was obtained by cutting the barrier film-attached substrate to pieces using scissors. The obtained spectra are shown in FIG. 5. Peak areas standardized by the Q⁴ peak area are shown in Table 3.

TABLE 3

| Chemical shift (ppm) | Belongingness | Integration ratio |
|---|---|---|
| −102.0 | Q³ | 5.0 |
| −112.0 | Q⁴ | 1.0 |

As shown in Table 3, with regard to the obtained spectra, an area ratio between Q³ and Q⁴ was calculated to obtain a ratio of Q³/Q⁴. From the calculation, Q³/Q⁴ was 5.0.

From the results of the above-described measurement, in the sample of Example 1 in which Q³/Q⁴ is less than 1, the water vapor permeability was relatively small, and thus high gas barrier properties were exhibited. In the samples (Comparative Examples 1 and 2) in which Q³/Q⁴ was 1 or more, the water vapor permeability was relatively large, and thus the samples were evaluated to have low gas barrier properties.

From these results, usefulness of the invention was confirmed.

### INDUSTRIAL APPLICABILITY

The laminated film of the invention has high gas barrier properties, and thus can be appropriately used in, for example, electronic devices.

### REFERENCE SIGNS LIST

10: Manufacturing apparatus
13 to 16: Conveying roll
17: First film-forming roll
18: Second film-forming roll
50: Organic EL device (electronic device)
100: Liquid crystal display device (electronic device)
400: Photoelectric conversion device (electronic device)
55, 105, 405: Laminated film (first substrate)
56, 106, 406: Laminated film (second substrate)
F: Film (substrate)
SP: Space (film-forming space)

1. A laminated film, comprising:
a substrate; and
at least one layer of film layer that is formed on at least one surface of the substrate,
wherein at least one layer of the film layer contains silicon, oxygen, and hydrogen,
a ratio of a total value of Q¹, Q², and Q³ peak areas to a Q⁴ peak area on the basis of an abundance ratio of silicon atoms having different bonding states to oxygen atoms, which are obtained by ²⁹Si solid-state NMR measurement of the film layer, satisfies the following conditional expression (I):
(total value of Q¹, Q², and Q³ peak areas)/(Q⁴ peak area)<1.0 (I),
wherein Q¹ represents a silicon atom that is bonded to one neutral oxygen atom and three hydroxyl groups, Q² represents a silicon atom that is bonded to two neutral oxygen atoms and two hydroxyl groups, Q³ represents a silicon atom that is bonded to three neutral oxygen atoms and one hydroxyl group, and Q⁴ represents a silicon atom that is bonded to four neutral oxygen atoms.

2. The laminated film according to claim 1,
wherein the film layer further contains carbon.

3. The laminated film according to claim 1,
wherein the film layer is a layer that is formed by a plasma chemical vapor deposition method.

4. The laminated film according to claim 3,
wherein a film-forming gas that is used in the plasma chemical vapor deposition method contains an organic silicon compound and oxygen.

5. The laminated film according to claim 4,
wherein the film layer is a layer that is formed under conditions in which a content of oxygen in the film-forming gas is set to be equal to or less than a theoretical amount of oxygen necessary to completely oxidize a total amount of the organic silicon compound in the film-forming gas.

6. The laminated film according to claim 3,
wherein the film layer is a layer formed using discharge plasma of a film-forming gas that is a forming material of the film layer, which is generated in a space between a first film-forming roll and a second film-forming roll by applying an alternatin-current voltage between the first film-forming roll around which the substrate is wound and the second film-forming roll that is opposite to the first film-forming roll and around which the substrate is wound downstream of a conveying route of the substrate in relation to the first film-forming roll.

7. The laminated film according to claim 6,
wherein the film layer is a layer that is formed by conveying the substrate to overlap first discharge plasma formed along tunnel-shaped magnetic fields by forming endless tunnel-shaped magnetic fields in a space between the first film-forming roll and the second film-forming roll that are opposite to each other, and second discharge plasma that is formed at the periphery of the tunnel-shaped magnetic field.

8. The laminated film according to claim 1,
wherein the substrate has a strip shape, and
the film layer is a layer that is continuously formed on the surface of the substrate while conveying the substrate in a longitudinal direction.

9. The laminated film according to claim 1,
wherein at least one kind of resin selected from the group consisting of a polyester-based resin and a polyolefin-based resin is used as the substrate.

10. The laminated film according to claim 9,
wherein the polyester-based resin is polyethylene terephthalate or polyethylene naphthalate.

11. The laminated film according to claim 1,
wherein the thickness of the film layer is 5 nm to 3000 nm.

12. The laminated film according to claim 1,
wherein in a silicon distribution curve, an oxygen distribution curve, and a carbon distribution curve which indicate a relationship between a distance from a surface of the film layer in a thickness direction of the film layer, and a ratio of an amount of silicon atoms (atomic ratio of silicon) to a total amount of silicon atoms, oxygen atoms, and carbon atoms, a ratio of an amount of oxygen atoms (atomic ratio of oxygen) to the total amount, and a ratio of an amount of carbon atoms (atomic ratio of carbon) to the total amount, respectively, all of the following conditions (i) to (iii) are satisfied,
(i) the atomic ratio of silicon, the atomic ratio of oxygen, and the atomic ratio of carbon satisfy a condition expressed by the following expression (1) in a region of 90% or more of the thickness of the layer:
(atomic ratio of oxygen)>(atomic ratio of silicon)>(atomic ratio of carbon) (1), or
the atomic ratio of silicon, the atomic ratio of oxygen, and the atomic ratio of carbon satisfy a condition expressed by the following expression (2) in a region of 90% or more of the thickness of the layer:
(atomic ratio of carbon)>(atomic ratio of silicon)>(atomic ratio of oxygen) (2),
(ii) the carbon distribution curve has at least one extremal value, and
(iii) an absolute value of a difference between a maximum value and a minimum value of the atomic ratio of carbon in the carbon distribution curve is 5% by atom or more.

13. An electronic device, comprising:
a functional element that is provided on a first substrate; and
a second substrate that is opposite to a surface of the first substrate on which the functional element is formed,
wherein the first substrate and the second substrate form at least a part of a sealing structure that seals the functional element in the inside of the sealing structure, and
at least one of the first substrate and the second substrate is the laminated film according to claim 1.

14. The electronic device according to claim 13,
wherein the functional element constitutes an organic electroluminescence element.

15. The electronic device according to claim 13,
wherein the functional element constitutes a liquid crystal display element.

16. The electronic device according to claim 13,
wherein the functional element constitutes a photoelectric conversion element that receives light and generates electricity.
